(19) United States
(12) Patent Application Publication
(10) Pub. No.: US 2020/0371574 A1
(43) Pub. Date: Nov. 26, 2020

(54) DATACENTER POWER MANIPULATION USING POWER CACHES

(71) Applicant: Virtual Power Systems, Inc., Milpitas, CA (US)

(72) Inventors: Shankar Ramamurthy, Saratoga, CA (US); Akshay Krishnamoorthy, Santa Clara, CA (US); Martin P. Leslie, San Jose, CA (US); Wade Floren Schott, Santa Clara, CA (US); Karimulla Raja Shaikh, Cupertino, CA (US)

(73) Assignee: Virtual Power Systems, Inc., Milpitas, CA (US)

(21) Appl. No.: 16/993,329

(22) Filed: Aug. 14, 2020

Related U.S. Application Data
(63) Continuation-in-part of application No. 15/381,049, filed on Dec. 15, 2016, now Pat. No. 10,747,289.
Application No. 15/381,049 is a continuation-in-part of application No. 14/526,140, filed on Oct. 28, 2014, now Pat. No. 10,128,684.
(60) Provisional application No. 63/052,476, filed on Jul. 16, 2020.
(60) Provisional application No. 63/039,000, filed on Jun. 15, 2020.
(60) Provisional application No. 62/992,186, filed on Mar. 20, 2020.
(60) Provisional application No. 62/267,961, filed on Dec. 16, 2015.
(60) Provisional application No. 62/057,127, filed on Sep. 29, 2014.
(60) Provisional application No. 62/047,593, filed on Sep. 8, 2014.
(60) Provisional application No. 62/033,618, filed on Aug. 5, 2014.
(60) Provisional application No. 62/029,226, filed on Jul. 25, 2014.
(60) Provisional application No. 61/985,617, filed on Apr. 29, 2014.
(60) Provisional application No. 61/970,390, filed on Mar. 26, 2014.
(60) Provisional application No. 61/931,667, filed on Jan. 26, 2014.
(60) Provisional application No. 61/896,504, filed on Oct. 28, 2013.

(51) Int. Cl. G06F 1/30; G06F 1/28; H02J 7/00; H05K 7/14

(52) U.S. Cl. CPC G06F 1/30; G06F 1/28; H02J 7/0013; H05K 7/1487; H02J 7/007182; H05K 7/1492; H02J 7/0047

(57) ABSTRACT

Disclosed techniques include power manipulation using power caches within a datacenter. The power caches store power for later use when power demand exceeds the power available. A power source is coupled across a plurality of data racks to a power load within a datacenter. A power cache is coupled to the power load. Power for the power load is provided from the power source. The power cache is enabled to provide power to the power load when power requirements of the power load exceed a power threshold. The power threshold is determined by a set of power policies for the datacenter. The enabling the power cache to provide power to the power load provides power bursting capability.

### RELATED APPLICATIONS

This application claims the benefit of U.S. provisional patent applications “Datacenter Power Management Using Current Injection” Ser. No. 62/992,186, filed Mar. 20, 2020, “Datacenter Current Injection for Power Management” Ser. No. 63/052,476, filed Jul. 16, 2020, and “Datacenter Power Management through Phase Balancing” Ser. No. 63/039,000, filed Jun. 15, 2020.

This application is also a continuation-in-part of U.S. patent application “Data Center Power Manipulation” Ser. No. 15/381,049, filed Dec. 15, 2016, which claims the benefit of U.S. provisional patent application “Energy Control by Peak Shaving and Source Pooling” Ser. No. 62/267,961, filed Dec. 16, 2015.

The U.S. patent application “Data Center Power Manipulation” Ser. No. 15/381,049, filed Dec. 15, 2016 is also a continuation-in-part of U.S. patent application “Energy Control Via Power Requirement Analysis and Power Source Enablement” Ser. No. 14/526,140, filed Oct. 28, 2014, which claims the benefit of U.S. provisional patent applications “Intelligent Control of Energy and Power Management” Ser. No. 61/896,504, filed Oct. 28, 2013, “Intelligent Power Control” Ser. No. 61/931,667, filed Jan. 26, 2014, “Dynamic Power Control Through Resource Allocation” Ser. No. 61/970,390, filed Mar. 26, 2014, “Dynamic Power Capacity Allocation” Ser. No. 61/985,617, filed Apr. 29, 2014, “Multi-Level Data Center Consolidated Power Control” Ser. No. 62/029,226, filed Jul. 25, 2014, “Multi-Level Dynamic Power Control Through Capacity Allocation” Ser. No. 62/033,618, filed Aug. 5, 2014, “Energy Control Via Power Requirement Analysis and Power Source Enablement” Ser. No. 62/047,593, filed Sep. 8, 2014, and “Intelligent Control Of Energy For Rack Level Consolidated Power Systems” Ser. No. 62/057,127, filed Sep. 29, 2014.

Each of the foregoing applications is hereby incorporated by reference in its entirety.

### FIELD OF ART

This application relates generally to power control and more particularly to datacenter power manipulation using power caches.

### BACKGROUND

Datacenters are facilities that house the computing and other electrical equipment required to support the information technology (IT) operations for an organization. These centralized facilities, sometimes called “server farms”, support a wide range of applications, data storage, and data access, among many other processing requirements. Organizations such as search providers, online retailers, financial institutions, research laboratories, universities, hospitals, and other computing-intensive organizations, conduct operations using their datacenters. A typical datacenter houses a network of varied, critical systems, the continuous operation of which is vital to the organization. The critical systems can include servers, storage devices, routers, and other IT equipment. The critical systems can be mounted in rows of equipment racks, also called data racks or information technology racks. Because the proprietary, confidential, and personal information stored on and processed by these critical systems must be protected, the security and reliability of datacenters and the information within them is a top priority for the organizations. Further, the wide range of processing requirements and the quantity of the equipment that performs the processing cause datacenters to consume significant amounts of power. In fact, the amount of power consumed by the datacenter typically accounts for a substantial portion of an organization's operating budget, just to cover the cost of electricity. The reliability and availability of the electrical power sources provided to these datacenters directly impact the reliability and availability of the datacenters. Organizations must acquire sufficient amounts of reliable power in order to keep their datacenters running smoothly. Further complicating the task of providing power, power demand can fluctuate widely based on various factors, such as processing job mix, the time of day, or even the season of the year. Thus, managing power within the datacenter becomes a critical aspect in many industrial applications, including administration of the datacenter. Any datacenter energy savings that can be achieved can translate into increased profits for an organization. Additionally, energy savings can provide additional dividends in terms of reduced wear and tear on power sources and reduced cooling costs, adding to the received benefit of an organization.

Computer systems are constructed from a vast number of electrical and electronic components, each of which consumes power. These components include printed circuit boards populated with integrated circuits or “chips”, mass storage devices based on magnetic or electronic storage technologies, networking interfaces, and processors. Given the precise and ever-increasing power requirements demanded by these components, reliable and efficient power delivery is crucial to operation of the datacenters. For many organizations, the computer systems must meet or exceed predetermined statutory requirements relating to reliability and availability. Financial institutions and healthcare organizations are required by law to meet certain standards for the protection of data. Additionally, educational organizations and retail businesses face other statutory requirements which demand that certain standards must be met to protect personal educational and consumer data. The statutory requirements often place stringent safeguards on the physical and technical security of personal data by mandating physical security of the systems and encryption of the data. Regardless of the computer system and infrastructure requirements of a given type of institution, key infrastructure requirements must be met in order to address the important issues of availability, reliability, job load, and other organizational requirements of datacenters. For example, the issue of effectively cooling a datacenter (i.e. the removal of excess heat) is a critical issue which must be addressed to ensure stable and reliable operation of the datacenter. Each of the many devices in the datacenter generates copious amounts of heat, whether the device is a server, a blade, a switch, a backup unit, a communications unit, or another device. The cooling of modern datacenters can directly impact the layout and design of the center. Some datacenters are arranged in so called “hot rows” and “cold rows,” where equipment generating excess heat is grouped together in “hot rows” and surrounded by rows of cooler-running equipment grouped in “cold rows,” The cold rows are named for their ability to serve as heat sinks for the hot rows, absorbing some of the excess heat from the “hot” equipment. Other centers are designed with cooling devices placed adjacent to significantly hot devices, where the cooling devices include fans, air conditioning units, water cooling systems, and so on.

Another significant aspect of datacenter design and administration involves providing sufficient power to the datacenter. Particularly in the case of high-reliability datacenters, such as those used for e-commerce, banking, airline reservations, video distribution, and the like, power can be provided by more than one power grid, while for other datacenters, power can be provided by a combination of a power grid and locally generated power. Thus, providing reliable and efficient power to the large number of computers and associated equipment in modern datacenters or server farms is an important aspect contributing to the performance of these operations.

### SUMMARY

The power requirements generated by a datacenter can be dynamic, based on the range of computing and electrical equipment that is required at a given time for processing computing tasks. Further, the power requirements are dependent on contractual requirements to provide a level of computing capability; reliability requirements such as redundant power grids for high-availability datacenters; statutory requirements for physical and electronic security, redundancy, and availability; and so on. The power requirements of the datacenter equipment often include AC loads and DC loads, depending on the type of equipment to which the power is being provided. The power requirements of the datacenter can vary over time based on application or job mix activity, planned maintenance, unplanned equipment failure, and other factors. The time-variable power requirements can include increases during normal business hours, and subsequent decreases after business hours and/or on weekends; changes in cooling requirements based on season; and so on. The makeup of AC load demand versus DC load demand can also change. Datacenters provide vital functions for businesses, governments, educational institutions, and other enterprises. Characterizing the behavior of datacenter power consumption is essential to maintaining consistent reliability of the datacenters. Power caches can be used to store power when excess power is available, then can provide power when power demands exceed available power. Power caches can be used more broadly within the datacenter to help enable 1N redundancy, 2N redundancy; to support carbon footprint management; to control the cost of energy; or to help select the source of energy.

Disclosed techniques enable datacenter power manipulation using power caches. The datacenter power manipulation can be based on power policies that are used to establish datacenter operating behavior based on limits for power consumption, power generation sources, carbon footprint reduction, and other criteria. A power cache can be used to store power when an amount of power available from one or more power sources exceeds an amount of power required by power loads. This excess power storage can also be performed based on the power generation costs, contractual requirements, etc. The power caches are used to supplement power provided by the power sources under conditions of peak power requirements. The storing of power within the power caches can also be controlled by the power policies. When power requirements remain below a threshold set forth in a power policy, the power caches are replenished. The replenished power caches are then used to provide power to meet peak power requirement demands. The power policies enable a convenient and effective way to manage the dynamic requirements of a modern datacenter. These policies enable increased power utilization and greater efficiency given a specific set of power sources and supplies. By use of policies, underused and unexploited power capabilities can be unlocked to enhance power utilization within a datacenter. In some cases, power policies can be employed to reduce overall costs of utility power provided to datacenters.

A processor-implemented method for power manipulation is disclosed comprising: coupling a power source across a plurality of data racks to a power load within a datacenter; coupling a power cache to the power load; providing power for the power load from the power source; and enabling the power cache to provide power to the power load when power requirements of the power load exceed a power threshold as determined by a set of power policies for the datacenter. In embodiments, the enabling the power cache to provide power to the power load comprises power bursting. In embodiments, the power policies are propagated from a datacenter controller to group controllers for the plurality of data racks. In embodiments, the group controllers report operating information to the datacenter controller. In embodiments, the power policies include a power policy for the power cache specifying a maximum duration of drain for the power cache. And in some embodiments, the power policies include a power policy for the power cache specifying a maximum duration for charging the power cache.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for datacenter power manipulation using power caches.

FIG. 2 is a flow diagram for calculating power requirements and determining policies.

FIG. 3 shows data rack power and control communication.

FIG. 4 illustrates fractional power sharing and control.

FIG. 5 illustrates peak shaving.

FIG. 6 illustrates 2N redundancy for power.

FIG. 7 shows limit allocation.

FIG. 8 illustrates hierarchical allocation of power control.

FIG. 9 shows control system internals.

FIG. 10 illustrates JSON code for policies.

FIG. 11 illustrates a system for datacenter power bursting.

FIG. 12 is a system diagram for power manipulation.

### DETAILED DESCRIPTION

Datacenters can contain hundreds, or even thousands, of computers and other associated equipment, such as disk arrays, data backup, routers, and other networking and storage equipment. Managing power distribution for efficiency and reliability can be challenging. This disclosure provides techniques for data manipulation using power policies. The power policies are powerful tools for establishing behaviors of the power distribution system within a datacenter. Given certain constraints, such as peak operating power, peak duration, availability of alternate power sources, and the like, policies regarding how power is to be allocated among various devices within the datacenter can be established.

In disclosed techniques, a datacenter can include multiple power sources. For example, a datacenter can include two main power sources, each main source being capable of providing power for the entirety of equipment within the datacenter. This configuration provides 2N redundancy. In some cases, a main source can include a grid source, such as power provided by a utility company via a substation. The main source can further include one or more alternate sources in the form of a locally generated power. Additionally, the main source can include a power cache. The power cache can include, but is not limited to, a battery, a capacitor, and/or an electromechanical source. An electromechanical source can include flywheel-based energy storage, where the flywheel is spun by a power source during an energy surplus condition, and the flywheel drives a generator to provide power during periods of increased energy demand. An electromechanical source can include pumps that pump water to a higher potential during a period of energy surplus and then release the water during a period of increased energy demand in order to generate electricity. An electromechanical source can include compressors that compress air in a tank to a higher pressure during a period of energy surplus and then release the compressed air to power a generator during a period of increased energy demand in order to generate electricity. Other electromechanical power caches are possible. The power cache can be replenished by one or more sources. In some cases, the power cache can be replenished from the grid via power utilities. In other cases, the power cache can be replenished from an alternate source such as a diesel generator set, solar power, wind power, water power, and/or tidal power generation.

The datacenters can have dynamic power requirements that result in uneven power consumption during operation. The dynamic power requirements can be attributable to factors such as job mix, user mix, time of day, day of month, time of year, etc. By use of power policies, datacenter power usage efficiency can be greatly increased and more processing units enabled with the same set of power sources. For example, a datacenter that is primarily used for overnight backup of data might have increased power consumption overnight, with lower power consumption during the day. In another example, a datacenter that is primarily used during business hours can have increased power consumption attributable to heating, ventilation, cooling, and air conditioning (HVAC); lighting; communications; and so on. Additionally, computerized load balancing can create conditions for dynamic power requirements that are unpredictable and require a fast response in order to accommodate them. For example, subscriber-based systems might have increased power requirements when many customers/users simultaneously log in to use a system or application. Exactly when the increased power requirements can occur may not be known a priori. Hence, the ability to establish power policies, including flexible policies, to define the behavior of power distribution within a datacenter under a variety of conditions, enables power manipulation that can keep a datacenter running efficiently under a variety of conditions. Policies can enable peak provisioning within the same power infrastructure and can thereby reduce demand on utility power sources and other power sources. Power caches can be used to address peak requirements and to increase overall capabilities given limited resources.

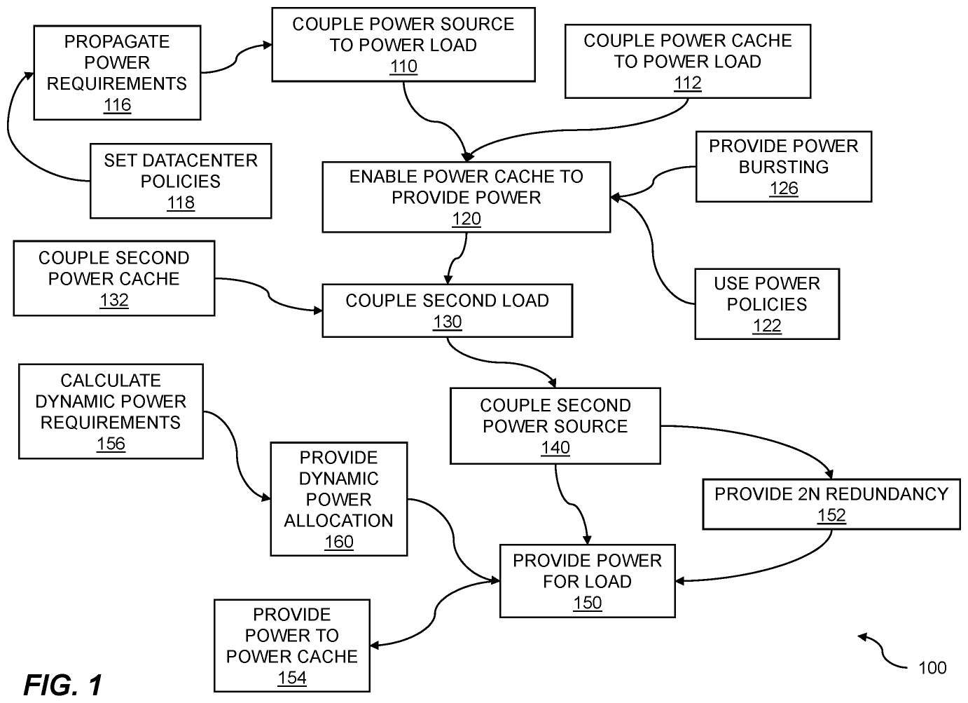

FIG. 1 is a flow diagram for datacenter power manipulation using power caches. The flow 100 illustrates a processor-implemented method for power manipulation. The flow 100 includes coupling a power source across a plurality of data racks to a power load within a datacenter 110. This can include connecting at least two main sources to the datacenter. In embodiments, each main source provides enough power for the entire datacenter. When two such main power sources are used, it is referred to as 2N redundancy. In cases where two main power sources are used, one of the power sources can be referred to as an “A feed” and the other power source can be referred to as a “B feed.” Within each main power source, multiple grid and/or alternate power sources and/or power caches can provide power. The flow 100 includes coupling a power cache to the power load 112. The power cache can include, but is not limited to, a battery, a capacitor, and/or an electromechanical power storage system. In some cases, the power cache can include an array of batteries. The batteries may include, but are not limited to, lead-acid, nickel metal hydride (NiMH), lithium ion (Li-ion), nickel cadmium (NiCd), and/or lithium ion polymer (Li-ion polymer) batteries. The flow 100 includes enabling the power cache to provide power 120. This can include a fractional power sharing and control scheme where the power cache supplies a percentage of the power for a main power source.

The flow 100 includes setting datacenter power policies 118. The power policies can include limits, along with one or more rules, to establish actions to be executed when the limits of the power policy are reached. Example limits can include, but are not limited to, power consumption limits, power storage limits, equipment operating temperatures, equipment operating durations, expected load requirements, ambient temperatures, and the like. More than one power policy can be used, forming a set of power policies. In embodiments, dynamically allocating power is based on the set of power policies. The set of power policies can include one or more of a power limit for the power source, a power limit for the power load, a minimum state of charge for the power cache, a maximum power assistance value for the power cache, or a drain rate for the power cache. The set of power policies can include a group power policy. The group power policy can include one or more of a power limit for a group of data racks, a target power value for a group of data racks, or a group power capacity limit. Embodiments include determining a data rack policy for a power supply within a data rack from the plurality of data racks, based on the group policy.

The power supply can perform power conditioning, voltage conversions, and/or other functions to provide suitable power for equipment installed in data racks. The flow includes propagating the power requirements 116 that are established in the policies. This can include propagating the requirements to power loads, power sources, and/or power cache devices. For example, a power policy can include a maximum continuous operation duration for a diesel generator, and a maximum downtime duration for the diesel generator. The maximum continuous operation can specify the maximum amount of time that the diesel generator can continuously operate. For example, if the maximum continuous operation is specified as three hours, then the value of three hours is propagated to a controller for the diesel generator. This protects the diesel generator from excessive wear and risk of overheating. Similarly, the maximum downtime duration can specify the maximum duration between activations of the diesel generator. For example, if the maximum duration between activations is set to ten days, then the value of ten days is propagated to the controller for the diesel generator. This means that, at a minimum, the diesel generator will be activated at least once within a ten-day period. This can help increase reliability of the diesel generator, since remaining idle for a long duration can cause reliability issues with internal combustion engines such as fuel spoilage, rubber parts deterioration, and so on. In other cases, a policy can be set so that a generator is used to handle peak power requirements for three or fewer hours. The power policy can specify an AC voltage based on a root-mean-square (RMS) average. The power policy can specify a power factor for a load, where the power factor (pf) is defined as the cosine of the phase difference between the current through and voltage across the load. These are just some of the examples of power requirements that can be propagated within the system. The power policy can also account for various system variables, such as the level in a fuel tank of a diesel generator, since the fuel level determines the amount of operation time possible for the generator. When the fuel level is below a predetermined threshold, the diesel generator can be taken offline until its fuel supply can be replenished.

Another such variable can be the coolant temperature of the diesel generator. If the coolant temperature exceeds a predetermined threshold, the diesel generator can be taken offline, and power can be retrieved from another power source. In some cases, power policies can be set for handling power caches. The power policy for a power cache can include a maximum duration of drain set for a power cache as well as a maximum duration for charging a power cache. Through the use of power caches, power usage can be flattened from utility grids. In some cases, power caches can be used to reduce the cost of power from utility grids by using the power caches to provide power when utility power cost is high, such as during the day, and charging the power caches from utility power when utility power cost is low, such as at night. In embodiments, the power policies specify regular intervals of time during which the power cache will be enabled and disabled. With power policies, more IT equipment can be deployed for the same power footprint usage to a datacenter.

The flow 100 includes using power policies 122. The flow 100 can further include providing power bursting 126. Power bursting is needed when either instantaneous load current requirements and/or instantaneous power grid source current availability cannot be met by a typical datacenter power topology. The flow 100 includes coupling a second load 130 to the power source. The second load can be an additional data rack, an additional cluster of data racks, and/or an additional group of data racks, where a group contains multiple clusters. The flow 100 includes coupling a second power source 140 to the system. Embodiments include coupling a second power source across the plurality of data racks. The second power source can include an alternate grid source, such as a second substation from the providing utility company. In this way, if a first substation shuts down, a second substation can continue to provide power. In some cases, the second power source 140 can include a local power source such as a diesel generator, solar panel array, wind turbine array, and/or hydroelectric power. In some cases, the first and second power sources can each be main power sources that can power the entirety of a datacenter. The solar panel array can include multiple solar panels. A solar panel is a packaged, connected assembly of photovoltaic cells. Each panel is rated by its DC output power under standard test conditions and typically ranges from 100 to 320 watts. Solar panels use light energy (photons) from the sun to generate electricity through the photovoltaic effect.

Embodiments include setting a group policy for the power source and a second power source. In such cases, the first and second power source can be configured to provide 2N redundancy 152. The flow 100 continues with providing power for the load 150. The flow 100 can include coupling a second power cache 132 to the power load and the second power load. The second power cache can include, but is not limited to, a battery, a capacitor, and/or an electromechanical power storage system.

The flow 100 includes calculating dynamic power requirements 156. Factors for calculating the dynamic power requirements can include, but are not limited to, expected usage (number of logged in users, active processes running, or the like) of the datacenter, actual usage of the datacenter, operating temperature of equipment, forecast weather conditions, and the like. For example, if the weather forecast is predicting an unusually hot weather pattern, the increase in overall power consumption for the area due to increased air conditioning usage can be anticipated. In such a case, it can be planned to supplement power to a datacenter with power caches during the anticipated peak power demand period for the area. Another factor can be expected peak usage times for a datacenter. For example, if a datacenter is involved in scheduled data backup operations, peak demand can be anticipated for the time of the backup operations. The flow 100 includes dynamically allocating power from the power source 160 across the plurality of data racks. This can include increasing the power allocation during the times of peak usage based on the calculated power requirements. The dynamically allocating power can be based on the set of power policies. In embodiments, dynamically allocating power from the power source and the second power source is based on the set of power policies. Furthermore, embodiments include dynamically allocating power from the power source and the second power source across the plurality of data racks. The dynamically allocating power from the power source and/or the second power source can be enabled using current injection.

The flow 100 includes providing power to a power cache 154. The power caches can be replenished based on the calculated power requirements. For example, during a period of hot weather in an area with high air conditioning usage, the available power from grid sources can be increased at night, while the temperature is cooler and the cost of power from grid sources is lower. During the periods of reduced ambient temperature, power can be provided to the power cache to replenish it for the next demand cycle. Through associated policies, reduced power costs can be obtained through using power caches when costs are high and recharging caches when power costs are lower. The power cache can include, but is not limited to, batteries, capacitors, and/or electromechanical systems such as water-based, compressed-air based, and flywheel-based systems. Thus, embodiments include providing power into the power cache when the power requirements of the power load are lower than limits for the power source. Power repatriation can be accomplished by restoring capabilities, using power policies that would otherwise be providing unneeded power overhead for a datacenter. Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

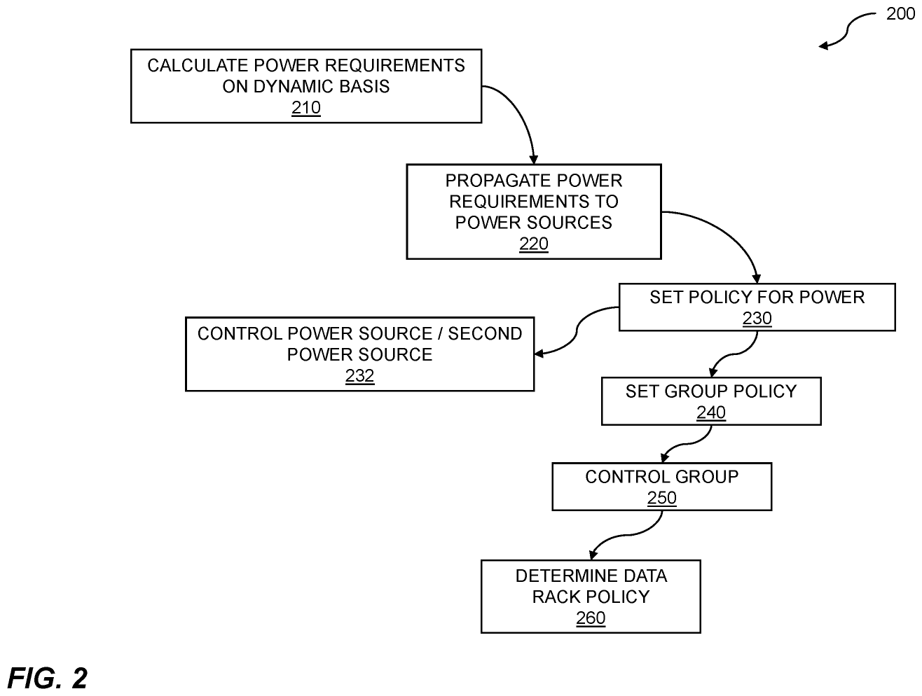

FIG. 2 is a flow diagram for calculating power requirements and determining policies. The flow 200 includes calculating the power requirements of the power load on a dynamic basis 210. The flow 200 can enable datacenter power manipulation using power caches. Factors for calculating the dynamic power requirements can include, but are not limited to, expected usage (number of logged in users, active processes running, or the like) of the datacenter, actual usage of the datacenter, operating temperature of equipment, forecast weather conditions, and the like. The flow 200 includes propagating information on the power requirements to the power sources 220. The information can include power cache parameters such as minimum charge levels, maximum charge levels, minimum number of charge/discharge cycles over a given duration, and the like. The information can include power load parameters, such as maximum peak power consumption. The information can include power source parameters, such as maximum supplied peak power, maximum supplied average power, maximum RPM value for a diesel generator, and the like. The flow 200 includes setting a power source policy for the power source and a second power source 230. The policy can include an upper limit on power to be provided, a duration of the power to be provided, or a reliability to be maintained. The policy can further include rules for activation of switches based on the state of a main source (feed).

The flow 200 includes controlling the power source 232 according to the power source policy that was set. This can include controlling a fractional contribution of a local source such as a diesel generator, as well as operating parameters for power source, such as, for example, a maximum operating duration for a diesel generator. In embodiments, the flow includes controlling the power source and the second power source according to the group policy that was set. The flow 200 includes setting a group policy 240 for the power source and a second power source. The flow 200 includes controlling the group 250 according to the group policy that was set. The flow 200 includes determining a data rack policy 260 for a power source within a data rack from the plurality of data racks, based on the group policy. In embodiments, a datacenter is comprised of multiple groups. Each group can be comprised of multiple clusters. Each cluster can be comprised of multiple data racks, and each data rack can include one or more computers, power caches, power supplies, and/or additional computer peripheral equipment. Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors.

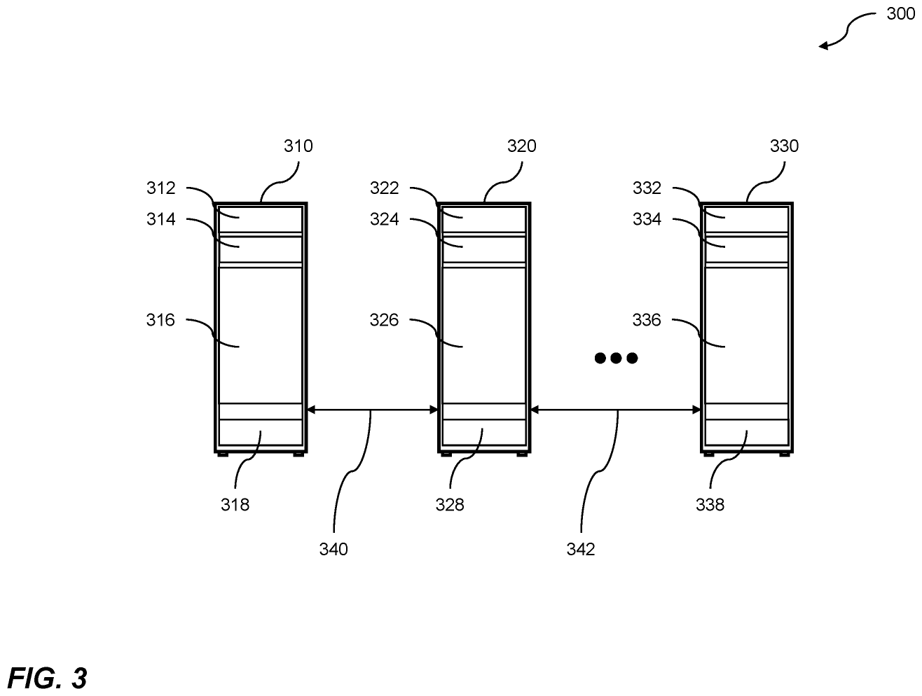

FIG. 3 shows data rack power and control communication. A datacenter can include multiple data racks. Example 300 includes three data racks, indicated as rack 310, rack 320, and rack 330. The example 300 can employ datacenter power manipulation using power caches. While three data racks are shown in example 300, in practice, there can be more or fewer data racks. The data rack 310 includes a power cache 312, a server 314, a server 316, and a power supply 318. The power supply 318 can be used for AC-DC conversion and/or filtering of power to be used by the servers 314 and 316, as well as replenishment of the power cache 312. In embodiments, the power cache 312 includes an array of rechargeable batteries. In embodiments, the batteries include, but are not limited to, lead-acid, nickel metal hydride (NiMH), lithium ion (Li-ion), nickel cadmium (NiCd), and/or lithium ion polymer (Li-ion polymer) batteries. Similarly, the data rack 320 includes a power cache 322, a server 324, a server 326, and a power supply 328. Furthermore, the data rack 330 includes a power cache 332, a server 334, a server 336, and a power supply 338. The data racks are interconnected by communication links 340 and 342. The communication links can be part of a local area network (LAN). In embodiments, the communication links include a wired Ethernet, Gigabit Ethernet, or another suitable communication link. The communication links enable each data rack to send and/or broadcast current power usage, operating conditions, and/or estimated power requirements to other data racks and/or upstream controllers such as a cluster controller. Thus, in the example 300, a power cache can be located on each of the multiple data racks within the datacenter. In embodiments, the power cache includes multiple batteries distributed across the multiple data racks.

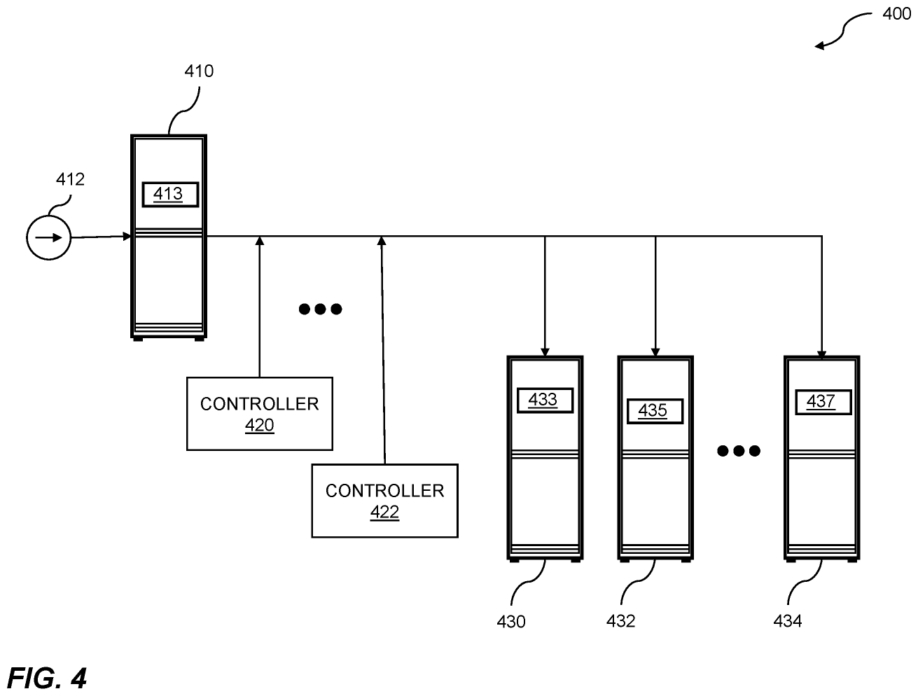

FIG. 4 illustrates fractional power sharing and control. Fractional power sharing and control can employ datacenter power manipulation using power caches. In the example 400, the power source and a second power source can share power to the multiple data racks, wherein the power is shared on a fractional basis. The example 400 includes a grid power source 412, and multiple secondary power sources. Each data rack includes a power cache within it, where the power cache can serve as a second power source. The data rack 410 includes a power cache 413. The data rack 430 includes a power cache 433. The data rack 432 includes a power cache 435. The data rack 434 includes a power cache 437. In embodiments, the power caches (413, 433, 435, and 437) include an array of rechargeable batteries. In embodiments, the batteries include, but are not limited to, lead-acid, nickel metal hydride (NiMH), lithium ion (Li-ion), nickel cadmium (NiCd), and/or lithium ion polymer (Li-ion polymer) batteries.

Each data rack includes a power load. In embodiments, the power load includes, but is not limited to, a computer, a disk array, a router, a printer, a network appliance, a network termination device, a bridge, an optical transmission driver, and/or another computer peripheral. Thus, as shown in example 400, there are multiple power loads, including a first power load and a second power load. The power source can provide power to the power load and the second power load. Furthermore, the power cache can provide power to the power load and the second power load.

A controller 420 and a controller 422 communicate with the data racks (410, 430, 432, and 434) in the example 400. While two controllers are illustrated in the example 400, in practice, there can be more or fewer controllers. In embodiments, the controllers are computers that are configured to receive data from the data racks. The data can include operating parameters such as current power consumption, peak power consumption, estimated future power consumption, current operating temperature, and the like. Additionally, warnings, alarms, and/or faults can be communicated to the controllers. The warnings can include over-temperature warnings, failed component errors, and the like. In some situations, a controller can shut down or disable an entire rack based on the communicated information from the data rack. In some situations, a controller can bring a different data rack out of standby to take the place of a data rack that has been shut down.

The controllers can implement fractional power sharing and control. For example, during a peak power demand period, eighty percent of the power can be provided by a grid power source 412, while the remaining twenty percent of the power can be provided by the power caches within each data rack. During periods of lower power consumption, the power caches are recharged, enabling them to be used again during a future period of increased power demand and consumption.

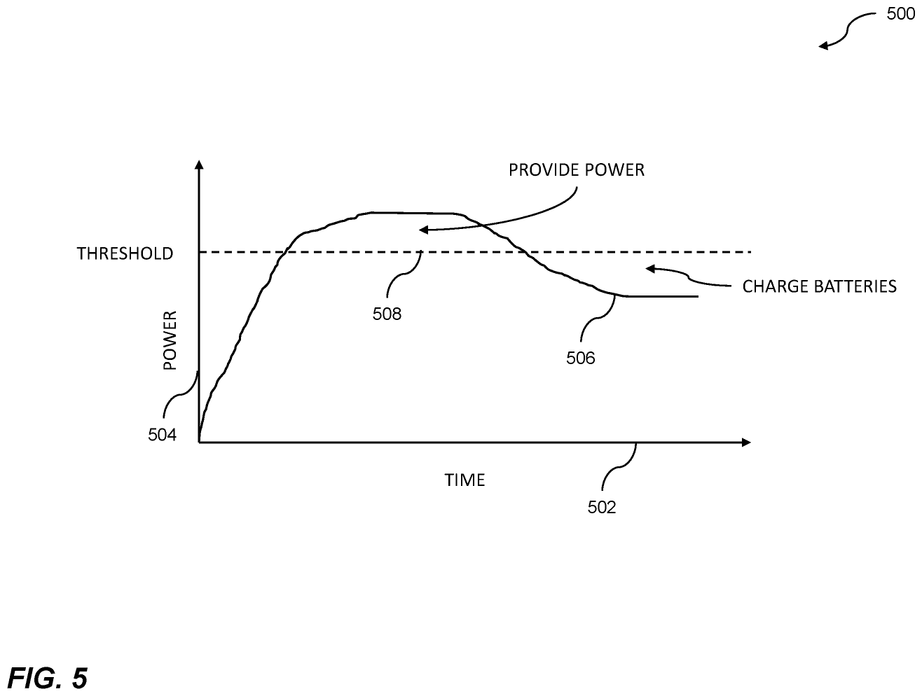

FIG. 5 illustrates peak shaving. Peak shaving can be enabled by datacenter power manipulation using power caches. A graph 500 includes a horizontal axis 502 representing time and a vertical axis 504 representing power consumption of a power load (such as a datacenter group, cluster, or data rack). A predetermined threshold 508 is established based on a power policy. The power policy can be defined by an administrator at the datacenter, a local power utility, or the like. The curve 506 represents the power consumption of a power load over time. During periods where the curve 506 is above the threshold 508, power is provided to the load by the power cache. During periods where the curve 506 is below the threshold 508, the power cache is replenished. In the case where the power cache comprises one or more batteries, the batteries are charged when the curve 506 is below the threshold 508. In embodiments, enabling the power cache comprises peak shaving.

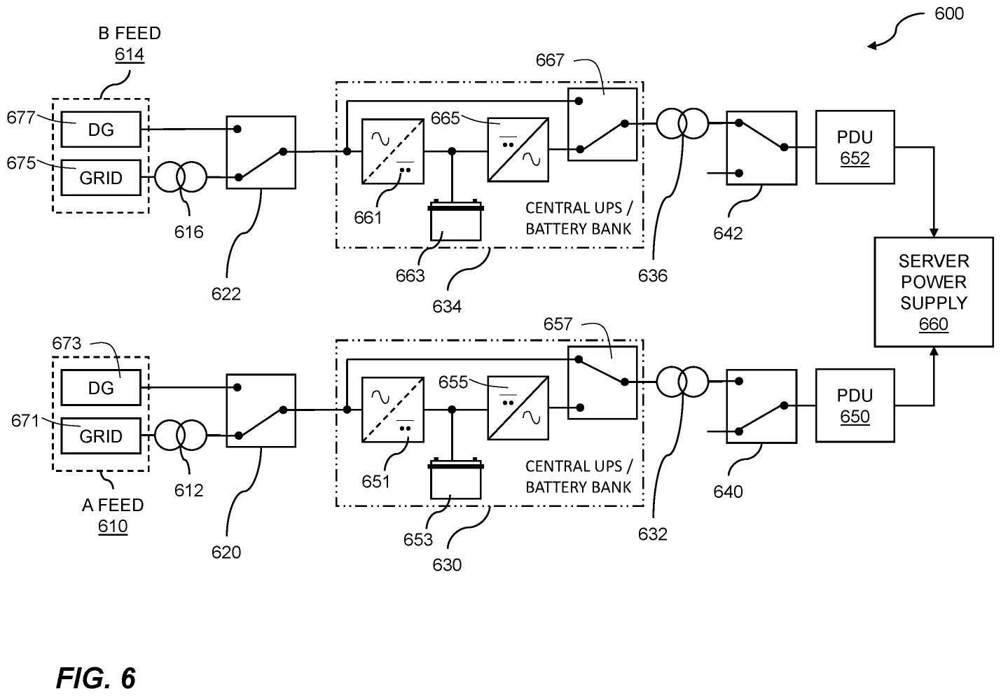

FIG. 6 illustrates 2N redundancy for power. The example 600 can employ datacenter power manipulation using power caches. The example 600 includes a first main power source 610, referred to as the “A feed.” The example 600 further includes a second main power source 614, referred to as the “B feed.” Each feed is capable of powering each device in the datacenter simultaneously. This configuration is referred to as 2N redundancy for power. The A feed 610 includes a grid source 671, and a secondary, local source of a diesel generator (DG) 673. The grid source 671 is input to a power regulator 612 and then into one input of a switch block 620. The diesel generator 673 is input to a second input of the switch block 620. The switch block 620 can be configured, based on a power policy, to select the diesel generator source or the grid source. The switch block 620 feeds into a power cache 630. The power cache 630 includes an AC-DC converter 651 configured to a charge battery 653, and a DC-AC converter 655 that feeds into an input of a switch block 657. The output of the switch block 620 feeds into a second input of the switch block 657. The output of the power cache 630 is input to a power regulator 632, and then to an input of a switch block 640. The switch block 657 can be configured, based on a power policy, to provide power from the power cache, or to bypass the power cache and provide power directly from the local or grid power source. The second input of the switch block 640 is not connected, such that if the second input is selected, the A feed 610 is disconnected from the PDU 650. The PDU (Power Distribution Unit) distributes power within a datacenter and feeds the server power supply 660 of a server within a data rack in the datacenter. In embodiments, the main datacenter power is distributed to multiple power distribution units (PDUs), typically rated from 50 kVA to 500 kVA, throughout the datacenter premises. The PDU can include transformer-based and/or non-transformer distribution units. PDUs can be supplied from centralized breakers and are generally placed along the perimeter of the space, throughout the room. The PDU can have a data rack form factor that allows placement adjacent to a row of data racks enabling power distribution closer to the load. Branch circuits are distributed from the PDUs to the data racks. Each data rack enclosure uses one or more branch circuits.

Similarly, the B feed 614 includes a grid source 675, and a secondary, local source of a diesel generator (DG) 677. The grid source 675 is input to a power regulator 616 and then into one input of a switch block 622. The diesel generator 677 is input to a second input of the switch block 622. The switch block 622 can be configured, based on a power policy, to select the diesel generator source or the grid source. The switch block 622 feeds into a power cache 634. The power cache 634 includes an AC-DC converter 661 configured to a charge battery 663, and a DC-AC converter 665 that feeds into an input of a switch block 667. The output of the switch block 622 feeds into a second input of a switch block 667. The switch block 667 can be configured, based on a power policy, to provide power from the power cache, or to bypass the power cache and provide power directly from the local or grid power source. The output of the power cache 634 is input to a power regulator 636, and then to an input of a switch block 642. The second input of the switch block 642 is not connected, such that if the second input is selected, the B feed 614 is disconnected from the PDU 652, which in turn feeds the server power supply 660 of a server within a data rack in the datacenter. Thus, the A feed 610 and the B feed 614 comprise a first main power source and a second main power source. The power source and the second power source can provide 2N redundancy to the power load. Furthermore, in embodiments, the power source and a second power source share power to the multiple data racks, wherein the power is shared on a fractional basis. Embodiments include coupling a second power load to the power source. Embodiments include coupling a second power cache to the power load and the second power load. In embodiments, the power cache provides power to the power load and the second power load. Furthermore, in embodiments, the power source provides power to the power load and the second power load.

As shown in the example 600, the system is currently configured, based on a power policy, such that the A feed 610 is disconnected from the server power supply 660 based on the mode of the switch block 640. The power cache 630 is currently set to bypass mode based on the mode of the switch block 657. The power source for the A feed is currently selected as the grid source 671 based on the mode of the switch block 620.

Furthermore, as shown in the example 600, the system is currently configured, based on a power policy, such that the B feed 614 is connected to the server power supply 660 based on the mode of the switch block 642. The power cache 634 is currently set to active mode based on the mode of the switch block 667, where power is being drawn from the battery 663. Thus, the switch block 667 is configured such that the power cache is enabled. Embodiments include coupling a power cache on each of the multiple data racks within the datacenter. The enabling the power cache can include peak shaving. The power source for the B feed is currently selected as the grid source 675 based on the mode of the switch block 622.

A variety of power policies can be established based on rules and limits for power loads, power sources, and power caches. The settings of the various switch blocks can be established as execution rules when certain criteria are met. In this way, power policies can reconfigure the various switch blocks for optimal operation under a variety of dynamically changing conditions. In embodiments, the power source and the second power source provide 2N redundancy to the power load.

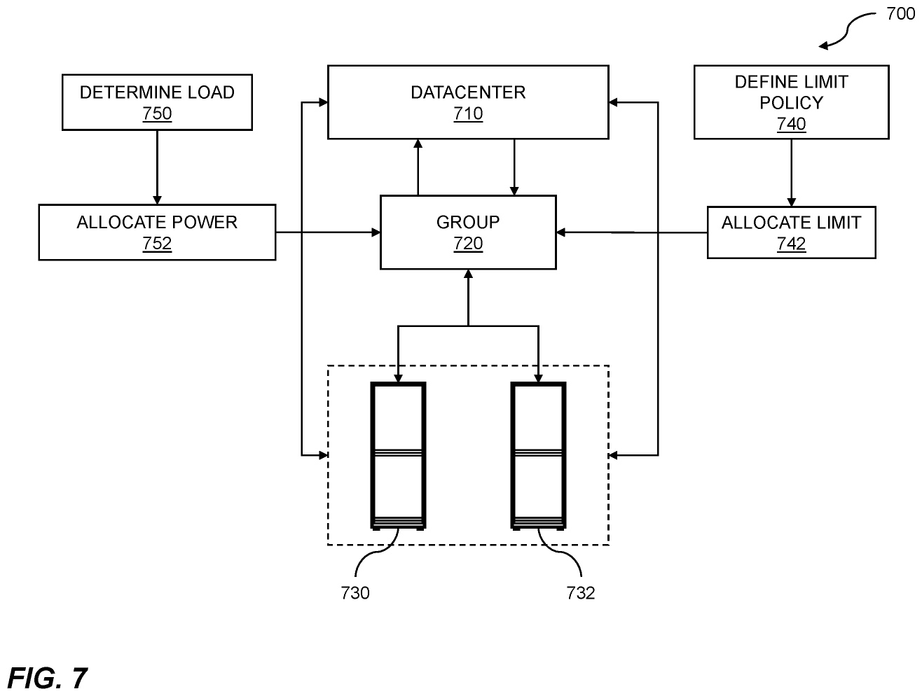

FIG. 7 shows limit allocation. Limit allocation can benefit from datacenter power manipulation using power caches. An example 700 includes a datacenter 710. The datacenter includes one or more groups, each group comprising one or more data racks. A limit policy is defined 740, which specifies a maximum amount of power that is allowed to be used. The limit is allocated 742 and provided to group 720. In the example 700, the load is determined 750. The load can be determined based on estimated data and/or can include factors based on actual performance reported by the data racks 730 and 732. The dynamic power allocation can allocate power 752 across the multiple data racks based on time-sensitive power requirements of power for each of the data racks within the multiple data racks.

Thus, the data racks 730 and 732 can comprise a power load. The limit policies can specify the amount of available power. The power is provided to a group, and the policies are propagated to the group and its hierarchical downstream devices. The group 720 can report power information for that group upstream to the datacenter 710. Power policies can determine which racks, clusters, and/or groups are fully enabled, partially enabled, and/or disabled, based on current power availability and power load requirements.

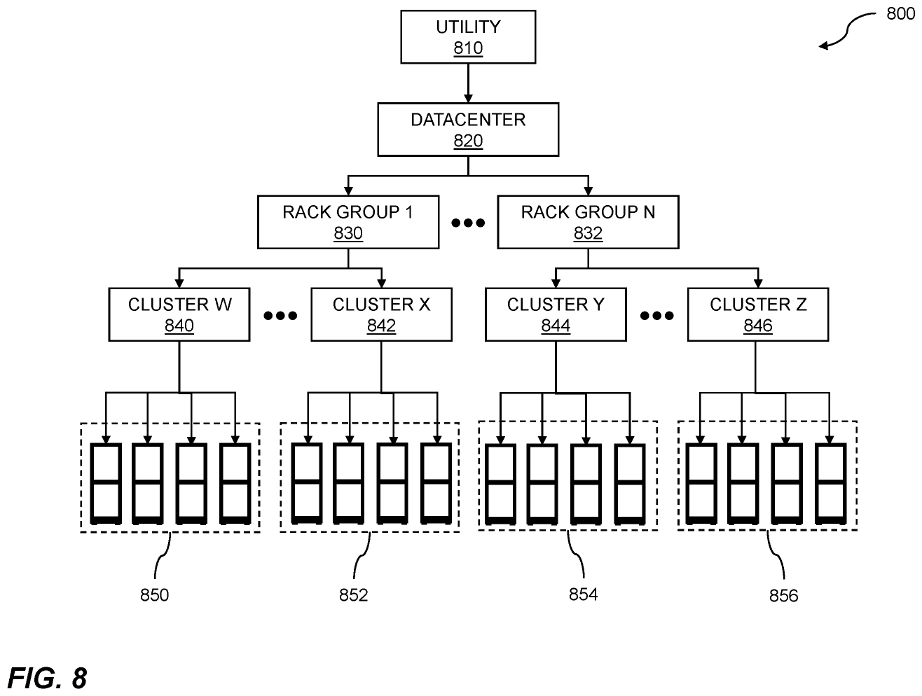

FIG. 8 illustrates hierarchical allocation of power control. Hierarchical allocation of power control can benefit from datacenter power manipulation using power caches. The example 800 includes a utility 810 as the top level of the hierarchy. The utility can include a local or regional energy provider. The example 800 further includes a datacenter 820 that receives power from the utility 810. Within the datacenter 820, the next downstream level of the hierarchy is the group level. The group level includes multiple groups, indicated as rack group 1 830 and rack group N 832. Each group can have a group policy. The group policy can include a hierarchical set of policies. Within the groups, the next downstream level of the hierarchy is the cluster level. The group 830 includes multiple clusters, indicated as cluster W 840 and cluster X 842. The group 832 includes multiple clusters, indicated as cluster Y 844 and cluster Z 846. Thus, in embodiments, the datacenter comprises a plurality of clusters of data racks. Each cluster includes multiple data racks. Cluster W 840 includes the data racks 850. Cluster X 842 includes the data racks 852. Cluster Y 844 includes the data racks 854. Cluster Z 846 includes the data racks 856. Thus, the datacenter can include a plurality of clusters of data racks. In embodiments, the power cache comprises multiple batteries distributed across the multiple data racks. Embodiments include dynamically allocating power from the power source across the plurality of data racks.

During operation of the system, power policies are propagated downstream from the datacenter 820 to the group level, and from the group level to the cluster level, and from the cluster level to the data rack level. The datacenter comprises multiple data racks. Operating conditions and/or power requirements are sent upstream. Thus, each data rack reports operating information to a cluster controller within its corresponding cluster. Each cluster reports operating information to a group controller within its corresponding group. Each group reports operating information to a datacenter controller. In this way, information, status, and operating conditions can quickly propagate through the system to allow power policies to act on that information in a timely manner.

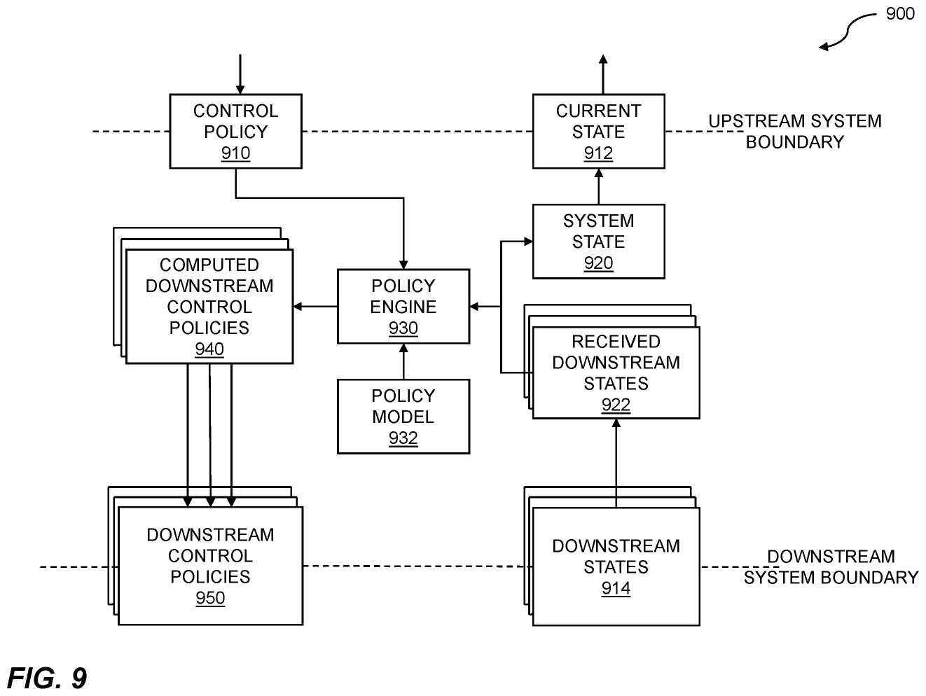

FIG. 9 shows control system internals. Control system internals can enable datacenter power manipulation using power caches. The example 900 includes a policy engine 930 that receives a policy model 932 and a control policy 910. This control policy can come from upstream and can be a power requirement from a higher level in the hierarchy. The control policy 910 can include an overall constraint or limit. For example, the control policy 910 can include establishing a maximum instantaneous consumption power limit of 1200 kW. The policy model 932 contains implementation rules for how to achieve the constraints of the control policy 910. For example, the policy model 932 can define rules for activating and/or deactivating power sources and/or power caches. The example 900 can include enabling the power cache to provide power to the power load when power requirements of the power load exceed limits of the power source, wherein the limits are defined by a set of power policies for the datacenter. The policy engine can then output computed downstream control policies 940 based on the policy model 932. These are passed down to the next lower hierarchy level as downstream control policies 950.

Downstream states 914 are passed upwards to be received by the downstream states 922 of the policy engine 930. The downstream states can include power consumption rates, estimated power demand, operating temperatures of equipment, overheating conditions, and the like. The policy engine 930 outputs a system state 920, which is passed upstream as the current state 912. In embodiments, states include, but are not limited to, online, offline, fault, cache enabled, cache disabled, cache charging, and/or cache discharging.

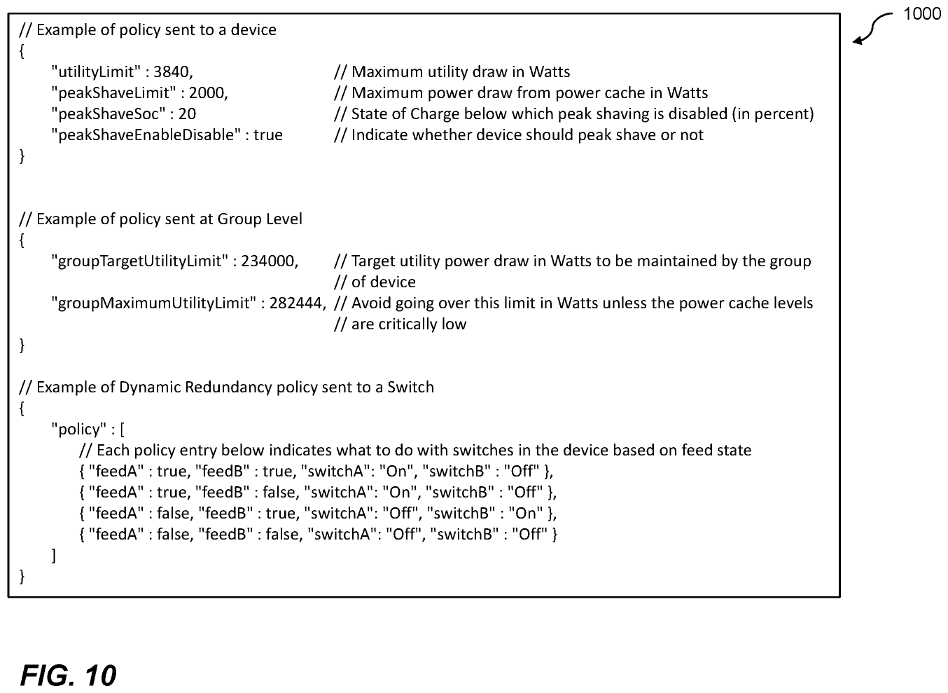

FIG. 10 illustrates JSON (JavaScript Object Notation) code for policies. The policies can be used for datacenter power manipulation using power caches. The set of power policies can include one or more of a power limit for the power source, a power limit for the power load, a minimum state of charge for the power cache, a maximum power assistance value for the power cache, or a drain rate for the power cache. As indicated in the example 1000, the policy can include a utility limit, which is a maximum utility draw in watts. The policy can include a peak shave limit, which is the maximum draw from a power cache in watts. The policy can include a peak shave state-of-charge, which is a level (in a percentage) of charge below which peak shaving is disabled. The policy can include a flag to enable or disable peak shaving.

The policy can include group level policies. In embodiments, a group level policy includes a group target utility limit, which is the target utility power draw in watts to be maintained by the group of devices. The group level policy can also include a group maximum utility limit, which represents a value to avoid exceeding unless power cache levels are critically low. In embodiments, the group policy includes a hierarchical set of policies.

The power policy can include dynamic redundancy control for switch blocks. This can include an array of rules based on the enabled/disabled state of main power sources. Given the state of the power sources, the various switch blocks (as shown in FIG. 6) can be configured for using power from or replenishing power to the power caches. Note that while the example 1000 shows a power policy implemented in JSON code, other methods of coding power policies are possible. These include, but are not limited to, a scripting language such as Python or Perl, a high-level programming language such as C or Java, and/or a table of limits and rules, such as a CSV-formatted list of limits and rules.

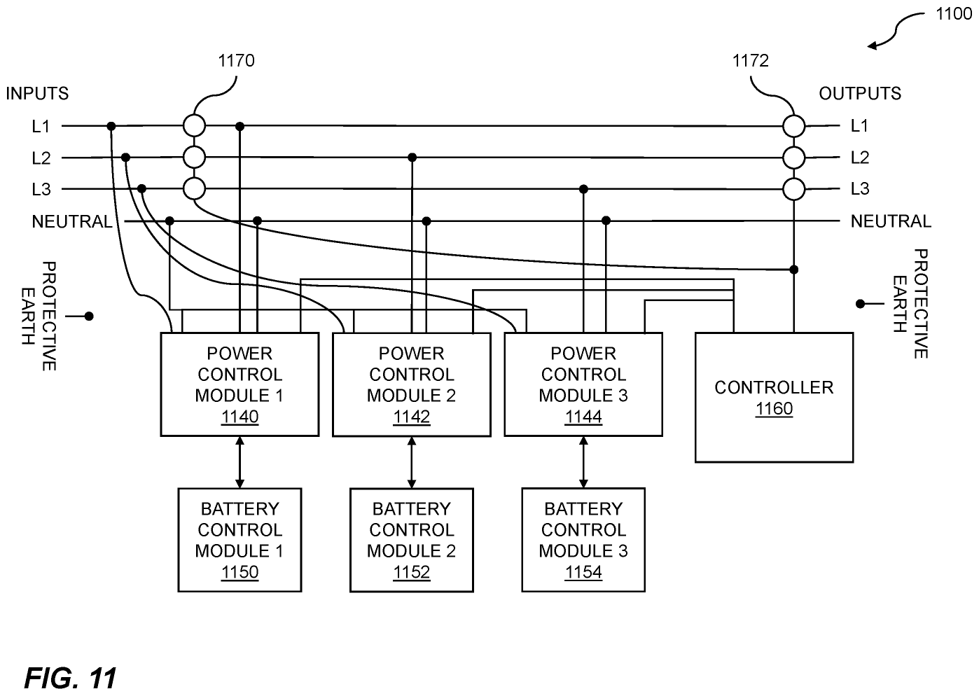

FIG. 11 illustrates a system for datacenter power bursting. Datacenter power bursting can be enabled by datacenter power manipulation using power caches. The system 1100 is a block diagram for power control module usage. One or more power control modules can be used convert or to store excess power, where the stored excess power can be used to meet an AC current requirement that can be in excess of available power. Power control module usage enables datacenter current injection for power management. A datacenter power policy is developed, and a supply capacity from a UPS is allocated. An AC current requirement is detected by one or more power control blocks, and AC current is injected into the output network of a UPS, by the power control blocks, based on the detecting and the datacenter power policy. Power control modules, such as power control module 1 1140, power control module 2 1142, and power control module 3 1144, can be coupled to one or more phases of input power. In the example shown, input three-phase power is shown. The one or more power control modules further can be coupled to neutral and protective earth. The one or more control modules can be coupled to one or more battery control modules such as battery control module 1 1150 coupled to power control module 1, battery control module 2 1152 coupled to power control module 2, battery control module 3 1154 coupled to power control module 3, and so on. Battery control modules are also parallelable in order to create a range of energy storage capacity options for any given power capacity associated with a power control module. A power control module and a battery control module can comprise a power control block.

The one or more power control modules can be controlled by a controller 1160. The controller can monitor current at the line inputs using one or more current sensors such as current sensor 1170. The controller can control storage of available AC power from the line inputs within batteries or capacitors, conversion of AC power to DC power, and DC power conversion to AC power using injection of AC current into an output power system, and so on. The controller can monitor an amount of AC current in an output network using one or more current sensors, such as current sensor 1172. Current sensors can be included within physical boundaries of the unit represented by the system block diagram 1100, or they can be moved external to the physical boundaries to support primary and auxiliary unit functionality. In embodiments, the AC current that can be injected by the one or more power control blocks can be sourced by at least one of the one or more power caches. A power cache can include one or more batteries, one or more capacitors, and so on, as part of the battery control modules 1150, 1152, and 1154. The power control blocks can be managed or controlled by the datacenter power policy, where the datacenter power policy can be issued to individual hardware components within a datacenter topology. The power control module system block diagram 1100 can describe elements of an energy block for use in datacenter power management.

Each power control module of the system 1100 can include a battery charging unit and a current mode grid tie inverter unit. The current mode grid tie inverter unit can enable current injection into a phase of the three-phase datacenter power grid at a constant voltage for the phase. The current mode grid tie inverter unit can enable current injection into a phase of the three-phase datacenter power grid at an in-phase AC frequency for the phase. The current mode grid tie inverter unit can inject current using pulse width modulation control. The pulse width modulation can be used to condition energy from the battery modules. The battery charging unit of power control modules 1140, 1142, and 1144 can be an integrated form of battery control modules 1150, 1152, and 1154, respectively, such that power control modules and/or battery control modules and/or power caches can be packaged in a discrete unit. Alternatively, the battery control modules can include the power caches, or they can be separately packaged. The battery modules can source energy for the power control modules.

The datacenter power management apparatus can enable power bursting within the datacenter. Power bursting is needed when either instantaneous load current requirements and/or instantaneous power grid source current availability cannot be met by a typical datacenter power topology. The inability can be based on latencies, impedances, current limits, and so on. The controller 1160 can manage operational modes for the datacenter power management apparatus, including modes for enabling power bursting, SLA fulfillment, redundancy requirements, etc. The operational modes can include charging and energy injection. The operational modes can be determined by a datacenter power management policy. The datacenter power management policy can enable power supply redundancy within the datacenter. The datacenter power management apparatus can be colocated with datacenter loads, and the colocation can be within a datacenter rack.

The power control modules can include communication signal inputs coupled to the controller 1160. The communication signal inputs can enable datacenter power policy execution. The controller 1160 can provide real-time or near-real-time response to current sense point sensors 1170 or 1172, whereas an overall datacenter processor running an overall datacenter policy may not be able to respond in real time due to processor and communication latencies.

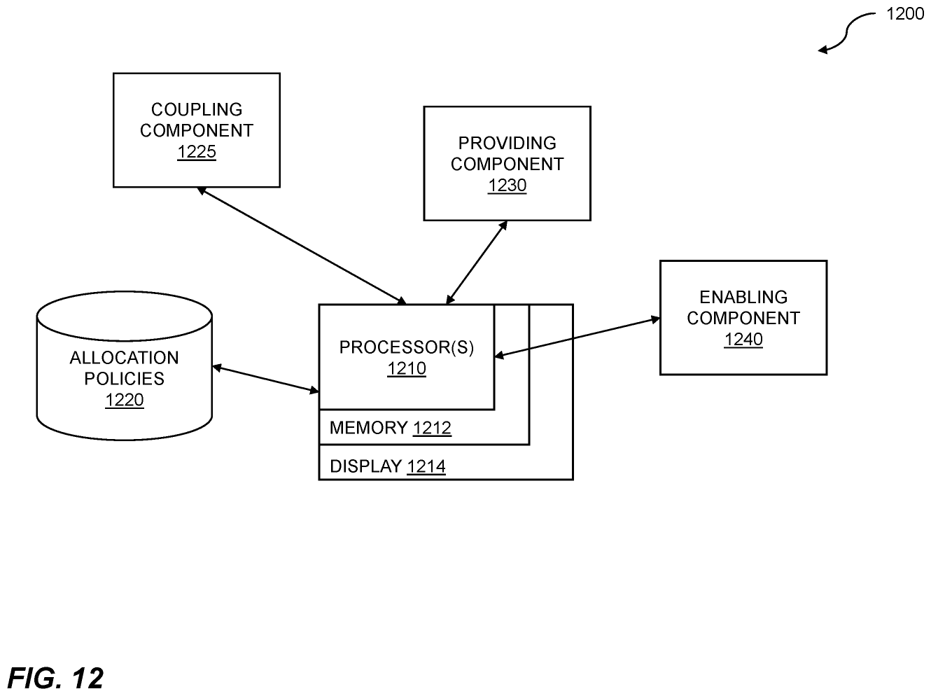

FIG. 12 is a system diagram for power manipulation. The system 1200 can implement datacenter power manipulation using power caches. The system 1200 can include one or more processors 1210 and a memory 1212 which stores instructions. The memory 1212 is coupled to the one or more processors 1210, wherein the one or more processors 1210 can execute instructions stored in the memory 1212. The memory 1212 can be used for storing instructions; for storing databases of power sources, power caches, and power loads; for storing information pertaining to load requirements; for storing information pertaining to redundancy requirements; for storing power policies; for system support; and the like. Information about the various power policies can be shown on a display 1214 connected to the one or more processors 1210. The display can comprise a television monitor, a projector, a computer monitor (including a laptop screen, a tablet screen, a net book screen, and the like), a cell phone display, a mobile device, or another electronic display.

The system 1200 includes allocation policies 1220. In embodiments, the allocation policies 1220 are stored in a networked database, such as a structured query language (SQL) database. The allocation policies 1220 can include limits, such as power consumption limits, as well as switch configurations when certain conditions are met. For example, when conditions allow peak shaving to take place, and surplus power exists, the power policies can identify switches and their configurations to allow replenishing of the power caches. The system 1200 further includes a coupling component 1225 that allows power sources to be coupled to power loads in a datacenter. The system 1200 can further include a providing component 1230 that provides power for the power load from the power source. The system 1200 further includes an enabling component 1240 that allows a power source, main power source, alternative power source, and/or a power cache, to be enabled or disabled.

The system 1200 includes a computer system for power manipulation comprising: a memory which stores instructions; one or more processors attached to the memory wherein the one or more processors, when executing the instructions which are stored, are configured to: couple a power source across a plurality of data racks to a power load within a datacenter; couple a power cache to the power load; provide power for the power load from the power source; and enable the power cache to provide power to the power load when power requirements of the power load exceed a power threshold as determined by a set of power policies for the datacenter.

Disclosed embodiments include a computer program product embodied in a non-transitory computer readable medium for power manipulation, the computer program product comprising code which causes one or more processors to perform operations of: coupling a power source across a plurality of data racks to a power load within a datacenter; coupling a power cache to the power load; providing power for the power load from the power source; and enabling the power cache to provide power to the power load when power requirements of the power load exceed a power threshold as determined by a set of power policies for the datacenter.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagrams and flowchart illustrations depict methods, apparatus, systems, and computer program products. The elements and combinations of elements in the block diagrams and flow diagrams, show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate, the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM), an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A processor-implemented method for power manipulation comprising:
coupling a power source across a plurality of data racks to a power load within a datacenter;
coupling a power cache to the power load;
providing power for the power load from the power source; and
enabling the power cache to provide power to the power load when power requirements of the power load exceed a power threshold as determined by a set of power policies for the datacenter.

2. The method of claim 1 wherein the enabling the power cache to provide power to the power load comprises power bursting.

3. The method of claim 1 wherein the power policies are propagated from a datacenter controller to group controllers for the plurality of data racks.

4. The method of claim 3 wherein the group controllers report operating information to the datacenter controller.

5. The method of claim 4 wherein the power policies include a power policy for the power cache specifying a maximum duration of drain for the power cache.

6. The method of claim 5 wherein the power policies include a power policy for the power cache specifying a maximum duration for charging the power cache.

7. The method of claim 6 wherein the power policies specify an AC voltage based on a root-mean-square average voltage.

8. The method of claim 7 wherein the power policies specify a power factor for the power load.

9. The method of claim 1 further comprising dynamically allocating power from the power source across the plurality of data racks.

10. The method of claim 9 wherein the dynamically allocating power is based on the set of power policies.

11. The method of claim 9 wherein the dynamically allocating power allocates power across the plurality of data racks based on time-sensitive power requirements of power for each of the data racks within the plurality of data racks.

12. The method of claim 1 further comprising coupling a second power source across the plurality of data racks.

13. The method of claim 12 wherein the power source and the second power source provide 2N redundancy to the power load.

14. The method of claim 12 further comprising dynamically allocating power from the power source and the second power source across the plurality of data racks.

15. The method of claim 14 wherein the dynamically allocating power from the power source and the second power source is based on the set of power policies.

16-19. (canceled)

20. The method of claim 1 further comprising anticipating the power requirements of the power load on a dynamic basis.

21. The method of claim 1 further comprising propagating information on the power requirements to the power source.

22. The method of claim 21 further comprising setting a power source policy for the power source.

23. The method of claim 22 further comprising controlling the power source according to the power source policy that was set.

24. The method of claim 1 further comprising setting a group policy for the power source and a second power source.

25. The method of claim 24 further comprising controlling the power source and the second power source according to the group policy that was set.

26-30. (canceled)

31. The method of claim 1 wherein the power policies specify regular intervals of time during which the power cache will be enabled and disabled.

32-35. (canceled)

36. A computer program product embodied in a non-transitory computer readable medium for power manipulation, the computer program product comprising code which causes one or more processors to perform operations of:
coupling a power source across a plurality of data racks to a power load within a datacenter;
coupling a power cache to the power load;
providing power for the power load from the power source; and
enabling the power cache to provide power to the power load when power requirements of the power load exceed a power threshold as determined by a set of power policies for the datacenter.

37. A computer system for power manipulation comprising:
a memory which stores instructions;
one or more processors attached to the memory wherein the one or more processors, when executing the instructions which are stored, are configured to:
couple a power source across a plurality of data racks to a power load within a datacenter;
couple a power cache to the power load;
provide power for the power load from the power source; and
enable the power cache to provide power to the power load when power requirements of the power load exceed a power threshold as determined by a set of power policies for the datacenter.
